(19) United States
(12) Patent Application Publication
(10) Pub. No.: US 2004/0119615 A1
(43) Pub. Date: Jun. 24, 2004

(54) Apparatus to provide fast data compression

(76) Inventors: Simon Richard Jones, Loughborough (GB); Jose Luis Nunez Yanez, Loughborough (GB); Mark John Milward, Loughborough (GB)

Correspondence Address: FINNEGAN, HENDERSON, FARABOW, GARRETT & DUNNER, LLP, 1300 I STREET, NW, WASHINGTON, DC, 20005, US

(21) Appl. No.: 10/470,719

(22) PCT Filed: Feb. 1, 2002
(86) PCT No.: PCT/GB02/00443

(30) Foreign Application Priority Data
Feb. 1, 2001 (GB) 0102572.5

(51) Int. Cl. H03M 7/00

(52) U.S. Cl. 341/50

(57) ABSTRACT

A lossless data compressor (10) has a content addressable memory dictionary (30) and a coder (38) having between them a critical path including a feedback loop forming a dictionary on path; circuit means (42) is connected in the feedback loop so that the dictionary can be updated from a previous comparison cycle at the same time as the coder codes a current comparison cycle; and run length encoding means (46) is connected to receive the output of the coder (38). The encoding means (46) is arranged to count the number of times a match consecutively occurs at a predetermined location in the dictionary (30), that is, the number of times the same search tuple is loaded into the same address of the dictionary. Two or more lossless data compressors may be arranged in parallel in accordance with an aspect of the invention.

This invention relates to apparatus for the lossless compression of data, and particularly to increasing the compression speed in comparison with known techniques.

In applicant's co-pending international patent applications WO 01/56168 and WO 01/56169 both having priority dates of the 25^{th} Jan. 2000, disclosures are made of respectively, a technique for more effective data compression, and a technique for improved compression speed. The disclosures of the aforesaid applications are incorporated herein by reference.

According to a first aspect of the present invention, a lossless data compressor characterised by a content addressable memory dictionary and a coder having between them a critical path including a feedback loop forming a dictionary adaptation path; circuit means connected in the feedback loop whereby the dictionary can be updated from a previous comparison cycle at the same time as the coder codes a current comparison cycle; and run length encoding means connected to receive the output of the coder, said encoding means being arranged to count the number of times a match consecutively occurs at a predetermined location in the dictionary.

Such an inventive arrangement incorporates both of the inventions covered by the two aforementioned applications. Such a compressor will be referred to as an “A-MatchPRO” compressor.

Further according to the invention, there is provided a lossless data compression system characterised by a plurality of data compressors arranged in parallel. The compressors may comprise that claimed in WO 01/56168, that claimed in WO 01/56169 or that in accordance with the first aspect of the present invention, the X-MatchPRO compressor.

Preferably the output of each compressor in the system is supplied in turn to a data output. Preferably compressed data is provided with flag means to indicate the length of compressed data from each compressor.

The invention further comprises the relevant data decompressors.

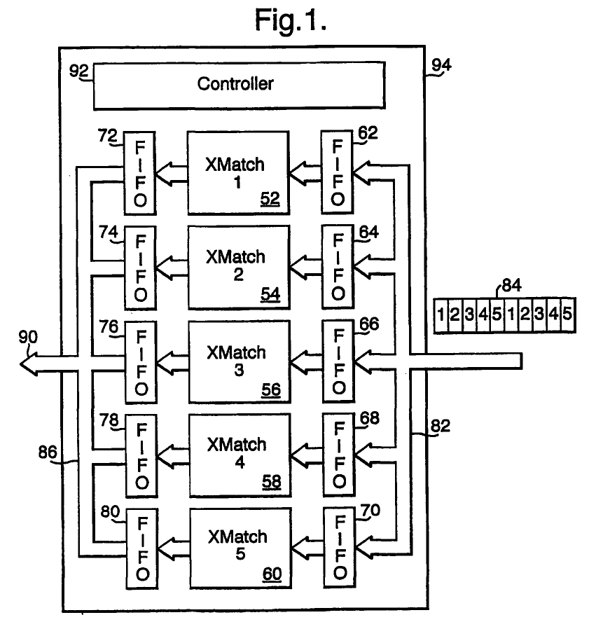

The invention will now be described by way of example only with reference to FIGS. 1-10 in which:

FIG. 1 illustrates a compressor/decompressor system comprising five X-Match compressors,

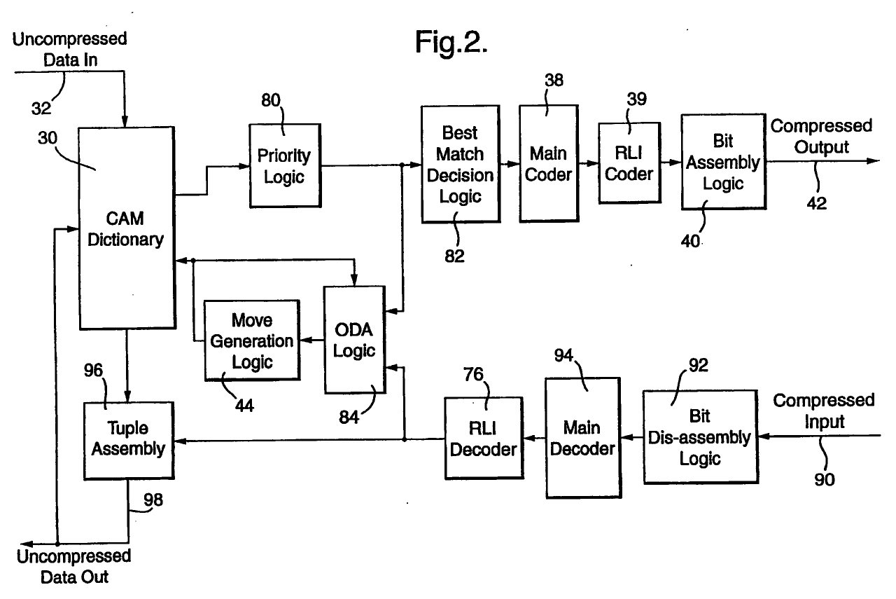

FIG. 2 illustrates a data compressor/decompressor as disclosed in WO 01/56168 to which the present invention may be applied,

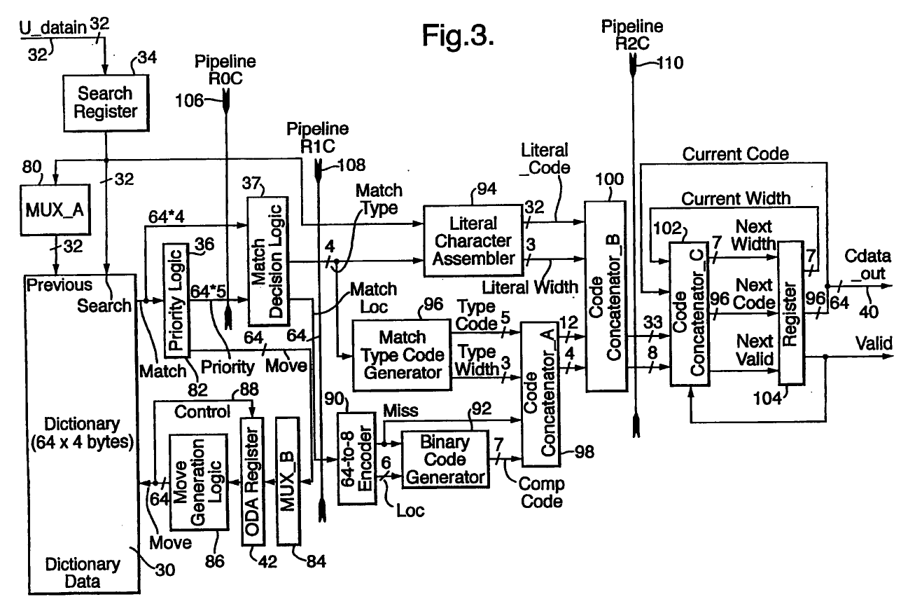

FIG. 3 illustrates a data compressor as disclosed in WO 01/56169 to which the present invention may be applied,

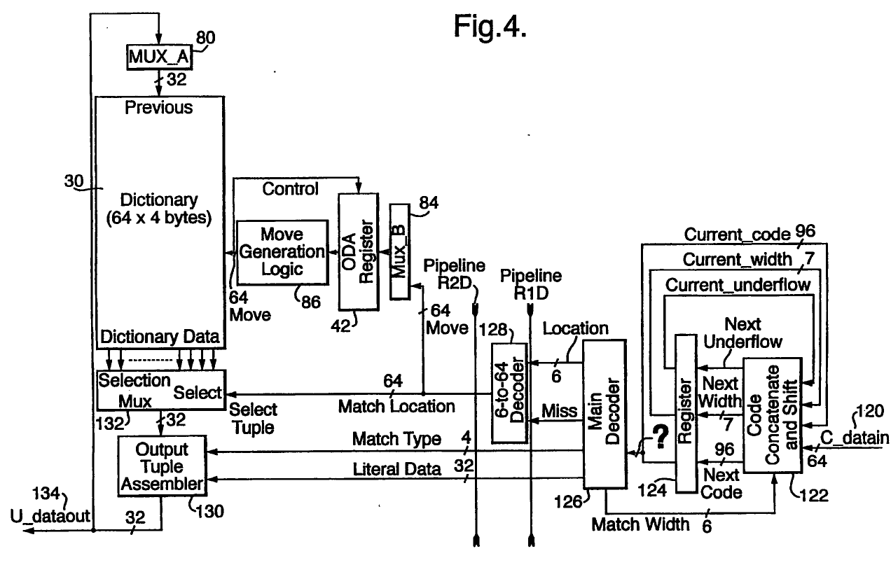

FIG. 4 illustrates a data decompressor as disclosed in WO 01/56169 to which the present invention may be applied,

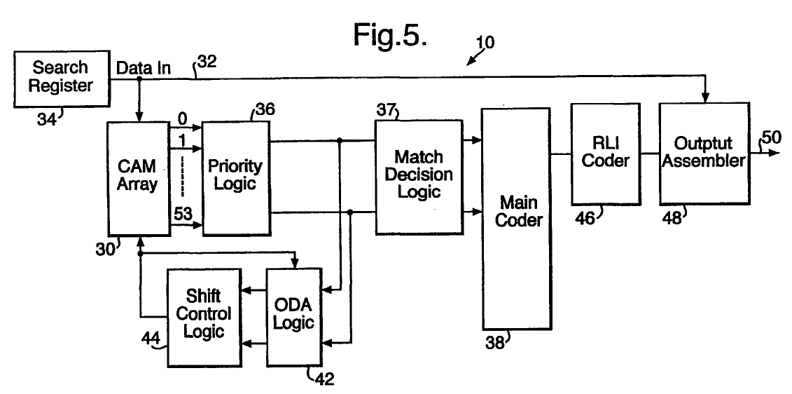

FIG. 5 illustrates schematically an X-MatchPRO compressor according to an embodiment of the invention,

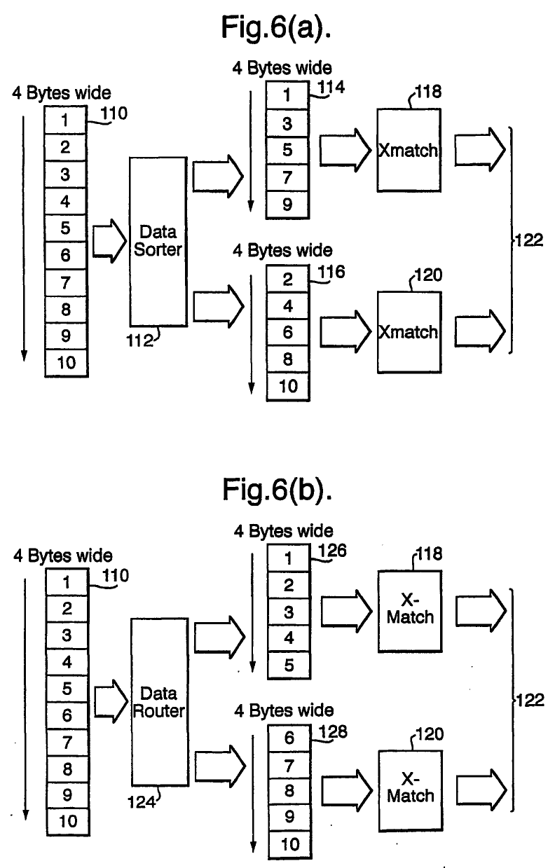

FIG. 6(a) and (b) illustrate two techniques for supplying data to a plurality of data compressors,

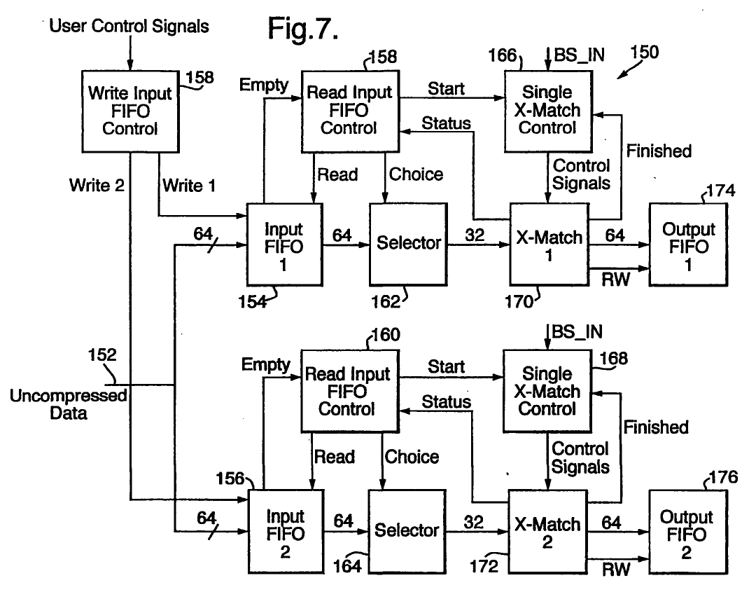

FIG. 7 shows a block schematic diagram of a two-compressor embodiment of the invention,

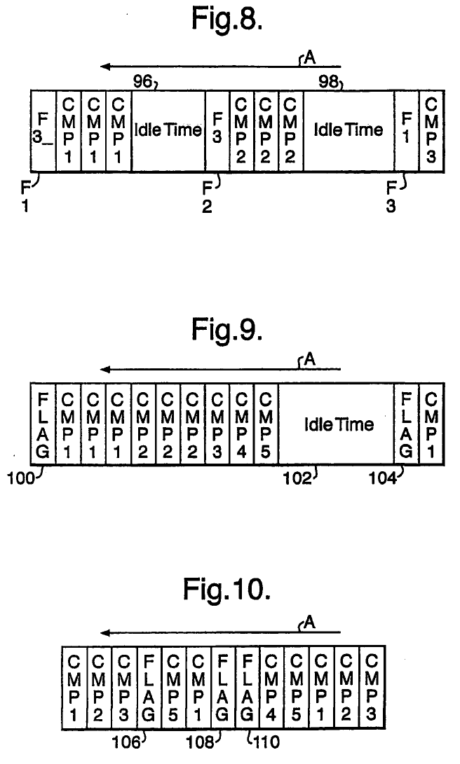

FIGS. 8, 9 and 10 illustrate three different arrangements by which compressed data is handled.

In FIG. 1, five lossless data compressors 52, 54, 56, 58, 60, labelled X-Match 1 to X-Match 5, are arranged in parallel to form a lossless data compression system 94. Each compressor has an input FIFO (First In First Out) circuit 62, 64, 66, 68, 70, and an output FIFO circuit 72, 74, 76, 78, 80. The input FIFOs 62-70 are connected together by an input bus 82 on which data to be compressed 84 is supplied. The output FIFOs 72-80 are connected together by an output bus 86 which supplies compressed data at output 90. A control system 92 provides control signals to the compressors and FIFOs, allowing appropriate control of the routing data into and out of the compression system 94.

In this example, each X-Match compressor 52-60 is a 4-byte design implemented in 0.15 micrometer CMOS ASIC technology. Each input FIFO 62-70 can store a block of data from the data to be compressed, which is larger than the compressor capacity, typically 64 bytes to 32 kbytes.

In operation, at start-up, the first block is sent to input FIFO 62 of the X-Match 1 compressor 52. When the first block has been sent, the next block is sent to input FIFO 64 of the X-Match 2 compressor 54, and so on. Once the fifth block of data has been to FIFO 80, the X-Match 1 compressor 62 is expected to have just finished compressing the first data block so the sixth data block is sent to input FIFO 62 and the cycle continues. As soon as data enters its associated FIFO, each X-Match compressor has data available to start compressing 4 bytes at a time, as described in detail in the co-pending patent applications.

Consider now the way in which the compressed data is handled, under the control of controller 94. The size of the compressed data block in the output FIFOs 72-80 depends on the type of input data, i.e. each block may have a different compression ratio. The three variations of handling compressed data described with reference to FIGS. 8, 9 and 10 allow for a design trade-off between compression and latency.

A detailed coder/decoder circuit disclosed in WO 01/56168 upon which an embodiment of the present invention may be based is shown in FIG. 2.

Uncompressed data 32 is supplied to the CAM dictionary 30, and the dictionary output, i.e. an indication of the dictionary address at which a match has been found, or the address of a partial match plus the unmatched byte or bytes, is supplied to a priority logic circuit 80, which assigns a different priority to each of the different types of possible matches in the dictionary, i.e. full partial or miss, and supplies the result to a match decision logic circuit 82. Circuit 82 uses the priority types to select one of the matches as the best for compression using the priority information and supplies a signal to a main coder 38.

The main coder 38 operates, as described in the prior art referred to above, to assign a uniform binary code to the matching location and static Huffman code to the match type, and concatenates any necessary bytes in literal form The compressed output is supplied to the RLI coder 39. This signal is produced by the main coder but is not shown in its diagram for simplicity. The RLI coder output passes to a bit assembly logic 40 which writes a new 64-bit compressed output to memory whenever more than 64 bits of compressed data are valid in an internal buffer (not shown). The output is compressed code 42.

The output from the priority logic circuit 80 is also supplied to an out-of-date adaptation (ODA) logic circuit 84, as described in our co-pending patent application no WO 01/56169. The output of the ODA circuit 84 is connected to a move generation logic circuit 44 which generates a move vector (as the adaptation vector applied in FIG. 3) depending on the match type and match location. The move generation logic 44 also provides a feedback signal to the ODA logic circuit 84.

For decompression, compressed input 90 is supplied to a bit disassembly logic circuit 92 which reads a new 64-bit compressed vector from memory whenever fewer than 33 bits are left valid in an internal buffer (not shown) after a decompression operation. The compressed vector is supplied to a main decoder 94 which decodes the match location and match type, together with any required literal characters and detects any possible RLI codes. The decoder 94 is connected to the RLI decoder 76 which supplies its run length decoded output to the ODA logic circuit 84 and also to a tuple assembly circuit 96.

The CAM dictionary 30 operates on the decoded input to regenerate 4 byte wide words which are supplied to the tuple assembly circuit 96; this circuit supplies uncompressed data 98, which comprises tuples assembled using information from the dictionary 30, plus any literal characters present in the code.

Application of Run Length Internal coding according to this arrangement has been found to achieve the compression improvement, which may be 10%, with little or no effect on the speed of compression. The improvement results from the efficient run length encoding of any repeating pattern, such as a 32 bit pattern. The most common repeating pattern is a run of 0s, but others are possible such as the space character in a text file or a constant background colour in a picture. Application of the invention allows efficient, lossless coding and decoding of such non-zero characters.

The Least Recently Used dictionary maintenance policy forces any repeating pattern to be located at position zero in the dictionary 30. Run Length Internal coding detects and codes any vector which is fully matched at position zero twice or more.

Such an arrangement offers a compression advantage in comparison with locating a run length encoder before the dictionary in a compression system, and since it uses the dictionary logic, complexity is kept to a minimum with a higher level of integration in the architecture.

The CAM dictionary 30 can have 15, 31 or 63 words; one position is already reserved for RLI events. A bigger dictionary improves compression but increases complexity significantly.

The uncompressed data-out 98 is identical to the data-in 32. There has been no loss.

The arrangement of FIG. 2 may be used in a system as shown in FIG. 1 to provide a multiple compressor arrangement according to an embodiment of the invention. A multiple decompressor embodiment may be provided similarly. An alternative compressor (& decompressor) architecture which can be connected in parallel to provide a multiple compressor (&decompressor) will now be described.

FIG. 3 shows a block schematic diagram of this further compressor. As is conventional, the number of bits on a connection is indicated adjacent to a bar crossing that connection.

The dictionary 30 is a 64 element CAM-based array, supplied with input data through a 32 bit wide search register 34. Data for search are provided directly to the dictionary 30 while a multiplexer 80 is arranged to select the search register during compression, and has an additional function during decompression (see FIG. 4).

The output of the dictionary 30 i.e. an indication of the dictionary address at which a match has been found, or the address of a partial match plus the unmatched bit, passes to a priority logic circuit 82, which transforms the 4 bit wide match to a 5 bit wide priority type for each location in the dictionary and supplies the priority type to the match decision logic circuit 37; circuit 37 also receives the output of the dictionary 30 directly. The circuit 37 uses the priority types to select the best match location for the compression process.

The ODA circuit 42 receives a signal from the priority logic circuit 36 through multiplexer 84; the multiplexer 84 is a 64 bit wide multiplexer arranged to select the active move vector depending on whether compression or decompression is active. The ODA circuit 42 is a 64 bit wide register and associated multiplexor circuitry which creates the out of date adaptation

The output of the ODA circuit 42, which is 64 bits wide, is supplied to a move generation logic circuit 86, which propagates a 64 bit wide match vector to generate the move vector to adapt the dictionary 30. The same vector, i.e. the current adaptation vector is fed back by the control path 88 of the ODA circuit 42 to adapt the next adaptation vector.

Turning now to the remainder of the apparatus illustrated in FIG. 3, which functions in a manner similar to that described in the prior art referred to above, the match decision logic circuit 37 supplies the match location to a 64-to-6 encoder 90 which transforms the uncoded 64 bit wide match location into a 6 bit wide coded match location The output of the encoder 90 passes to a binary code generator 92 which concatenates the miss or match bit to the match location.

The match decision logic circuit 37 also supplies a match type signal to a literal character assembler 94, which constructs the literal part of a compressed code for non-matched bytes, and to a match type code generator 96 which creates static Huffman code for the match types. The match types code and match type width signals from the match type code generator 96, and the compressed code from the binary code generator 92, pass to a first code concatenator 98 which assembles code for the match type and match location. A second code concatenator 100 receives output from concatenator 98 and also literal code and literal width signals from the literal character assembler 94 and provides output to code concatenator 102 which assembles the current compressed code with previous compressed code. Concatenator 10 outputs signals next width, next code, and next valid to a register 104, which is a 96 bit wide output register for the data and a 7 bit wide register for the length of valid data bits. The register 104 outputs compressed data 40, and also a valid signal, which is fed back to code concatenator 102 together with the current code and a current width signal from the register 104.

Pipelines R0C, R1C, R2C, respectively references 106, 108 and 110, indicate pipeline registers of the compression path.

FIG. 4 illustrates a corresponding single decompression circuit The dictionary 30, multiplexer 80, multiplexer 84 and ODA circuit 42 and move generation logic circuit 86 are connected as for the compression circuit.

Compressed data in, reference 120, is supplied to a code concatenate and shift circuit 122 which assembles new compressed data with old compressed data and shifts out data which has been decompressed The signals next underflow, next width (7 bits) and next code (96 bits) pass to a register 124 for temporary storage of compressed data. The register output is supplied to a main decoder 126, which decodes compressed code of a maximum 33 bits into 6 bit location address, 4 bit match type, and 32 bit literal data. Both the 6 bit location address and miss signals pass to a 6 to 64 decoder 128 which decodes a 6 bit coded dictionary address into its uncoded 64 bit equivalent.

The match type and literal data signals pass from the main decoder 126 to an output tuple assembler 130.

The 6 to 64 decoder 128 passes match location signal to the multiplexer 84. The ODA circuit 42, the move generation logic circuit 86 and the dictionary 30 operate to decompress the compressed data, working in the reverse to the compression process. The multiplexer 80 selects a newly formed tuple for application to the dictionary 30. The dictionary data is supplied to a selection multiplexer 132 which also receives a selected tuple signal from the 6-to-64 decoder 128. The selective multiplexer 132 selects one tuple out of the dictionary and supplies it to the output tuple assembler 130 which assembles the literal data and the dictionary word, depending on the type of match which has been decompressed.

The uncompressed data-out 134 is identical to the data-in 32. There has been no loss. As for the compressor/decompressor of FIG. 2, the compressor of FIG. 3 and the decompressor of FIG. 4 may be parallelised to give higher speed compression and decompression.

In FIG. 5, the inventions described in detail in the co-pending applications referred to above are merged into a single compressor 10, called an X-MatchPRO compressor.

A dictionary 30 is based on CAM technology and is supplied with data to be searched 32 by a search register 34. The dictionary searches in accordance with the X-Match algorithm, and is organised on a Move To Front (MTF) strategy and least Recently Used (LRU) policy.

The dictionary output is connected to a priority logic 36 which is connected through a match decision logic 37 to a main coder 38. The match decision logic circuit 37 also provides signals to a circuit 42 which will be referred to as Out-of-Date Adaptation (ODA) register, the ODA circuit 42 supplies a shift control logic circuit 44 which supplies “move” signals to the dictionary 30.

The arrangment is such that the dictionary 30 is updated on a Out-of-Date basis; a next adaptation vector t to be supplied to the dictionary is s into a current adaptation vector t+1 and at the same time the dictionary is updated; the transformation and updating are performed by the current adaptation vector after each search step.

The main coder 38 provides signals to a coder 46 which will be referred to as a “Run Length Internal” (RLI) coder, which provides signals to an output assembler 48. The assembler 48 provides an output stream of compressed data 50.

Again, the arrangement of FIG. 5 may be incorporated into an architecture as shown in FIG. 1 to provide a multiple compressor system. The same applies to the corresponding decompressor.

It will be appreciated that the performance of the compression system will be affected by the order and quantity of the search tuples applied to each of the compressors. FIG. 6 gives a simple example to illustrate this with only a pair of X-Match data compressors.

In FIG. 6(a) an input data stream 110 comprising tea 4-byte tuples is applied to a data sorter 112 which routes the incoming tuples alternately into a first data stream 114 and a second data stream 116. This alternate routing is referred to as an “interleaved” arrangement Consequently, the first data stream comprises tuples 1, 3, 5, 7 and 9 while the second data stream comprises the tuples 2, 4, 6 , 8 and 10. The first data stream is coupled to a first X-Match data compressor 118 and the second data stream is coupled to a second X-Match data compressor 120. The outputs of the two compressors are combined to provide output 122.

In FIG. 6(b) an input data stream 110 comprising ten 4-byte tuples is applied to a data router 124 which routes the tuples in blocks of five into a first data stream 126 and a second data stream 128. This routing technique is referred to as a “blocked” arrangement (Note that typically a much larger number of tuples will comprise a block—five is used here for simplicity). Consequently, the first data stream comprises tuples 1, 2, 3, 4 and 5 while the second data stream comprises the tuples 6, 7, 8, 9 and 10. The first data stream is coupled to a first X-Match data compressor 118 and the second data stream is coupled to a second X-Match data compressor 120. The outputs of the two compressors are combined to provide output 122.

The interleaved technique results in very low latency because there is no delay in deriving compressed data from each of the X-Match compressors while the blocked technique provides better compression because each X-Match compressor is able to exploit the redundancy in the incoming data stream. It has been found that, for the majority of applications, the interleaved technique provides too little compression to be acceptable. Arrangements for trading the latency of the multiple compressors with the compression are discussed further below with reference to FIGS. 8, 9 and 10.

FIG. 7 shows a more detailed block diagram of a simple two-compressor arrangement 150 in accordance with an embodiment of the present invention. Uncompressed data 152 is fed to a first input FIFO (First In, First Out buffer) 154 and to a second input FIFO 156. Because each of the X-Match compressors can handle four bytes per clock cycle the data should be arranged to arrive at a rate 4n to minimise latency where n is the number of X-Match compressors. Each of the FIFOs 154, 156 is provided with a respective WRITE signal from a WRITE INPUT FIFO CONTROL 158. This controller controls the start of compression as well as the size of data blocks to be handled. For example, Input FIFO 154 is written-to until the required block size is reached and then the WRITE signals are reversed so that data is written to Input FIFO 156.

Under the control of READ INPUT FIFO CONTROL 158, 160 the Input FIFO in each channel passes 64 bits to a SELECTOR 162, 164 every two clock cycles —the first 32 bits are sent on the first clock cycle and the second 32 bits are sent on the second clock cycle. The FIFO Controller 158, 160 also provide a START signal to X-Math controllers 166, 168 respectively and these provide control signals to their respective X-match compressors 170, 172. The compressed data is supplied to respective output FIFOs 174, 176. The combination of data from these FIFOs is discussed below to maintain the order of the data (to facilitate decompression).

A first arrangement for handling compressed data from a plurality of X-Match compressors is shown in FIG. 8. Each output FIFO 72-80 is arranged to provide a flag F indicating the size of the compressed data block. When the data is output, the flag is sent first. In FIG. 8, flag F1 precedes the data in CMP1 indicating data compressed by X-MatchPRO compressor 52; flag F2 precedes data in CMP2 indicating data compressed by X-MatchPRO compressor 54, and flag P3 precedes data in CMP3 indicating data compressed by X-MatchPRO compressor 56. The arrow A indicates the direction of flow of the data stream. Compressed data from each compressor 52-56 with its flag is provided to input 90 as soon as it is available, i.e. as soon as a compressor has processed the whole block stored in its input FIFO.

Since the compression ratios of each compressed block vary, there is inevitably Idle Time between each flag and compressed block as indicated at 96 and 98 when there is no valid data output because the next compressor has not yet finished compressing its input block.

Turning now to decompression, a system identical to system 94 (FIG. 1) is used as a decompressor when the compressed data reaches its destination. The flag F1 reaches the input bus first and indicates to the controller 92 how many words are to be directed to input FIFO 62 of X-MatchPRO 1 now acting as a decompressor, how many words to input FIFO 64 and so on.

In this first arrangement, at the output 90, there is some deterioration in compression by the parallel system 94 of five compressors in comparison with the compression available from a single compressor, because the flags and Idle Time are included in the output. This loss in compression tends to zero as the block size increases due to the fixed overhead of flag per block of compressed data. Idle time represents wasted time in outputting the data. Latency is introduced because a whole block of data, equal to the capacity of the input FIFO, needs to be compressed by each compressor before there is any output at 90.

In a second variation illustrated in FIG. 9, the controller 92 is arranged to control the system 94 so that compressed data is not sent from output 90 until all five compressors 52-60 have compressed their data blocks. A single flag 100 is used to provide information on the size of each compressed block, i.e. three words in CMP1 from compressor 52; three words in CMP2 from compressor 54; and one word each in CMP3, CMP4 and CMP5 from compressors 56, 58 and 60. The outputted data words with their flag 100 are succeeded in the data flow by Idle Time 102 before the next flag 104 and further compressed data words.

In this second arrangement, the latency of the system is increased in comparison with the first arrangement, but the compression of the data is not significantly worse than the compression which would be provided by a single X-MatchPRO compressor because there is a significant reduction in the number of flags required, i.e. one instead of five.

In the third variation shown in FIG. 10, instead of waiting for a whole block of data to be compressed by each compressor, each compressor outputs a small part corresponding to the amount of data it can process at a time. The compressor output CMP1 of the first four bytes of data input from the X-MatchPRO 1 compressor 52 is sent to the output 90, then the X-MatchPRO 2 compressor 54 sends its first compressed 4 bytes CMP2 to the output 90, then compressor 56 sends CMP3. If the next compressor 58 has not yet compressed its first 4 bytes so that it has no data ready to be output from its output FIFO, a flag 106 is sent to indicate no data is present and output CM5 is then taken from compressor 60, then continuing the cycle output CMP1 from compressor 52.

In the example of FIG. 10, neither compressor 54 nor 56 is ready to send data so two flags 108, 110 are sent and data CMP4 is output from compressor 58. Subsequently compressors 60, 52, 54 and 56 in order are all ready to send output data CMP5, CMP1, CMP2 and CMP3 without intervals.

By using a flag to indicate that the next compressor has not yet produced an output corresponding to 4 bytes of input, latency of the data has been reduced to that of a single X-MatchPRO compressor, but at the expense of decreased compression. Data or flags are always being sent, so there is no Idle Time in the data stream.

Table 1 shows the relative values of compression, speed of compression, and latency for the three different arrangements of output described with reference to FIGS. 8, 9 and 10 for the FIG. 5 arrangement of 5 X-MatchPRO compressors in parallel, and also shows those values for a single X-MatchPRO compressor.

TABLE 1

| | Compression | Speed | Latency |
|---|---|---|---|
| Single X-MatchPRO | 1 | 1 | 1 |
| Parallel Variation 1 | <1 | 5 | >1 |
| Parallel Variation 2 | 1 | 5 | >>1 |
| Parallel Variation 3 | <<1 | 5 | 1 |

One of the three variations in dealing with output data can be selected, depending on the requirements of the type of data currently being compressed.

By use of five X-MatchPRO compressors arranged in parallel, an increase in compression speed from 625 M bytes per second to 3.2 G bytes per second is achievable.

While the present invention has been described by way of example the invention encompasses any novel feature described herein whether explicitly or implicitly or any generalisation thereof.

1. A lossless data compression system (94) comprising a plurality of lossless data compressors arranged in parallel, each data compressor comprising a content addressable memory dictionary (30) and a coder (38), characterised by run length encoding means (39) connected to receive the output of the coder (38), said encoding means (39) being arranged to count the number of times a match consecutively occurs at a predetermined dictionary location.

2. A system according to claim 1 in which the dictionary (30) of each compressor is arranged so that at each search step a search tuple is loaded into the same address (50) of the dictionary.

3. A system according to claim 2 in which the run length encoder register means (39) of each compressor is arranged to count the number of times the same search tuple is loaded into the same address (50) of the dictionary (30).

4. A system according to claim 2 or claim 3 in which a further address (56) in the dictionary (30) of each compressor is reserved to indicate the number of times a search tuple is repeated.

5. A lossless data compression system (94) comprising a plurality of lossless data compressors, each data compressor comprising a dictionary (30) based on content addressable memory and a coder (40) having between them a critical path including a feedback loop forming a dictionary adaptation path, characterised by circuit means (42) connected in the feedback loop whereby the dictionary can be updated using data from a previous comparison cycle at the same time as the coder codes a current comparison cycle.

6. A system according to claim 5 in which said previous adaptation cycle for the compressors is the next but one previous cycle.

7. A system according to claim 5 or claim 6 in which the circuit means (42) is arranged to update the dictionary of each compressor in accordance with a preceding data element while a current data element is being processed by the dictionary.

8. A lossless data compressor (10) characterised by a content addressable memory dictionary (30) and a coder (38) having between them a critical path including a feedback loop forming a dictionary adaptation path, circuit means (42) connected in the feedback loop whereby the dictionary can be updated from a previous comparison cycle at the same time as the coder codes a current comparison cycle; and run length encoding means (46) connected to receive the output of the coder (38), said encoding means (46) being arranged to count the number of times a match consecutively occurs at a predetermined location in the dictionary (30).

9. A lossless data compression system (94) characterised by a plurality of lossless data compressors (52, 54, 56, 58, 60) each according to claim 8 arranged in parallel.

10. A system according to any one of the claims 1 to 7 or claim 9 in which the output of each of the plurality compressors (52, 54, 56, 58, 60) is supplied in turn to a data output (90).

11. A system according to any one of the claims 1 to 7, claim 9 or claim 10 in which compressed data is provided with Flag means to indicate the length of compressed data from each compressor (52, 54, 56, 58, 60).

12. A system according to any one of the claims 1 to 7 or any one of the claims 9 to 11 further comprising means for providing a compressed data block from each compressor with a flag F1, F2, F3, indicating the length of that compressed data block.

13. A system according to any one of the claims 1 to 7 or any one of the claims 9 to 11 further comprising means for providing the compressed data from the plurality of compressors with a single flag (100) indicating the length of each compressed data block from each compressor.

14. A system according to any one of the claims 1 to 7, or any one of the claim 9 to 11 in which each compressor is arranged to output in turn compressed data corresponding to its processing capacity, and if the next compressor has not yet finish processing, a flag 106, 108, 110 is inserted to indicate that compressor.

15. A lossless data compression system according to any one of the claims 1 to 7, or any one of the claims 9 to 14, further comprising means for alternating search tuples among the plurality of compressors.

16. A lossless data compression system according to any one of the claims 1 to 7, or any one of the claims 9 to 14, further comprising means for providing a plurality of adjacent search tuples to each of the plurality of data compressors.

17. A decompression system for decompressing data compressed by a data compression system defined in any one of the claims 1 to 16.

18. A method of lossless data compression, the method comprising arranging and operating a plurality of lossless data compressors in parallel, each data compressor comprising a content addressable memory dictionary and a coder, run length encoding means connected to receive the output of the coder, said encoding means being arranged to count the number of times a match consecutively occurs at a predetermined dictionary location.

19. A method of lossless data compression comprising arranging and operating a plurality of lossless data compressors in parallel, each data compressor comprising a dictionary based on content addressable memory and a coder having between them a critical path including a feedback loop forming a dictionary adaptation path, characterised by circuit means connected in the feedback loop whereby the dictionary can be updated using data from a previous comparison cycle at the same time as the coder codes a current comparison cycle.

20. A method of lossless data compression comprising arranging and operating a plurality of lossless data compressors in parallel, each compressor comprising a content addressable memory dictionary and a coder having between them a critical path including a feedback loop forming a dictionary adaptation path; circuit means connected in the feedback loop whereby the dictionary can be updated from a previous comparison cycle at the same time as the coder codes a current comparison cycle; and run length encoding means connected to receive the output of the coder, said encoding means being arranged to count the number of times a match consecutively occurs at a predetermined location in the dictionary.
